(19) United States
(12) Patent Application Publication
(10) Pub. No.: US 2015/0076506 A1
(43) Pub. Date: Mar. 19, 2015

(54) SEMICONDUCTOR DEVICE

(71) Applicant: KABUSHIKI KAISHA TOSHIBA, Tokyo (JP)

(72) Inventors: Takaaki Yasumoto, Kanagawa (JP); Naoko Yanase, Tokyo (JP); Kazuhide Abe, Kanagawa (JP); Takeshi Uchihara, Saitama (JP); Yasunobu Saito, Ishikawa (JP); Toshiyuki Naka, Ishikawa (JP); Akira Yoshioka, Ishikawa (JP); Tasuku Ono, Ishikawa (JP); Tetsuya Ohno, Ishikawa (JP); Hidetoshi Fujimoto, Kanagawa (JP); Shingo Masuko, Ishikawa (JP); Masaru Furukawa, Hyogo (JP); Yasunari Yagi, Hyogo (JP); Miki Yumoto, Kanagawa (JP); Atsuko Iida, Kanagawa (JP)

(73) Assignee: KABUSHIKI KAISHA TOSHIBA, Tokyo (JP)

(21) Appl. No.: 14/215,321

(22) Filed: Mar. 17, 2014

(30) Foreign Application Priority Data
Sep. 13, 2013 (JP) 2013-191128

(51) Int. Cl. H01L 29/20; H01L 29/40

(52) U.S. Cl. CPC H01L 29/2003; H01L 29/40
USPC 257/76; 257/734

(57) ABSTRACT

This disclosure provides a semiconductor device which includes a GaN-based semiconductor layer having a surface with an angle of not less than 0 degree and not more than 5 degrees with respect to an m-plane or an a-plane, a first electrode provided above the surface and having a first end, and a second electrode provided above the surface to space apart from the first electrode, having a second end facing the first end, and a direction of a segment connecting an arbitrary point of the first end and an arbitrary point of the second end is different from a c-axis direction of the GaN-based semiconductor layer.

### CROSS-REFERENCE TO RELATED APPLICATION

This application is based upon and claims the benefit of priority from Japanese Patent Application No. 2013-191128, filed on Sep. 13, 2013, the entire contents of which are incorporated herein by reference.

### FIELD

Embodiments described herein relate generally to a semiconductor device.

### BACKGROUND

A GaN-based semiconductor device having a high breakdown strength and capable of reducing power loss is expected to be applied to, for example, a semiconductor device for power electronics or a high-frequency power semiconductor device. However, the GaN-based semiconductor device has many problems of the reliability to be solved, such as current collapse.

### BRIEF DESCRIPTION OF THE DRAWINGS

FIGS. 1A and 1B are a schematic diagram of a semiconductor device of a first embodiment;

FIG. 2 is a view showing a crystal structure of a GaN-based semiconductor;

FIG. 3 is an explanatory view of electrode arrangement of the semiconductor device of the first embodiment;

FIG. 4 is an explanatory view of the operation and effect of the semiconductor device of the first embodiment;

FIG. 5 is an explanatory view of the operation and effect of the semiconductor device of the first embodiment;

FIG. 6 is a schematic top view of a semiconductor device of a second embodiment;

FIG. 7 is an explanatory view of electrode arrangement of the semiconductor device of the second embodiment;

FIGS. 8A and 8B are schematic diagrams of a semiconductor device of the third embodiment;

FIG. 9 is a schematic top view of a semiconductor device of a fourth embodiment;

FIGS. 10A and 10B are schematic diagrams of a semiconductor device of a fifth embodiment;

FIGS. 11A and 11B are schematic diagrams of a semiconductor device of a sixth embodiment;

FIGS. 12A and 12B are schematic diagrams of a semiconductor device of a seventh embodiment;

FIG. 13 is an explanatory view of electrode arrangement of the semiconductor device of the seventh embodiment;

FIG. 14 is a schematic top view of a semiconductor device of an eighth embodiment;

FIG. 15 is a schematic top view of a semiconductor device of a ninth embodiment;

FIGS. 16A and 16B are schematic diagrams of a semiconductor device of a tenth embodiment;

FIG. 17 is a schematic top view of a semiconductor device of an eleventh embodiment;

FIG. 18 is a schematic top view of a semiconductor device of a twelfth embodiment;

FIGS. 19A and 19B are schematic diagrams of a semiconductor device of a thirteenth embodiment;

FIGS. 20A and 20B are schematic diagrams of a semiconductor device of a fourteenth embodiment;

FIG. 21 is an explanatory view of electrode arrangement of the semiconductor device of the fourteenth embodiment;

FIGS. 22A and 22B are schematic diagrams of a semiconductor device of a fifteenth embodiment; and

FIGS. 23A and 23B are schematic diagrams of a semiconductor device of a sixteenth embodiment.

### DETAILED DESCRIPTION

A semiconductor device according to an embodiment includes: a GaN-based semiconductor layer having a surface with an angle of not less than 0 degree and not more than 5 degrees with respect to an m-plane or an a-plane; a first electrode provided above the surface and having a first end; and a second electrode provided above the surface to space apart from the first electrode, having a second end facing the first end, and a direction of a segment connecting an arbitrary point of the first end and an arbitrary point of the second end is different from a c-axis direction of the GaN-based semiconductor layer.

Hereinafter, embodiments of this disclosure will be described with reference to drawings. In the following description, the same components are denoted by the same reference numerals, and thus description of the components having been already described will be suitably omitted.

In this specification, a “GaN-based semiconductor” is a general term of a semiconductor including GaN (gallium nitride), AlN (aluminum nitride), InN (indium nitride), and an intermediate composition thereof. In this specification, AlGaN means a semiconductor represented by the composition formula: AlₓGa₁₋ₓN (0<x<1).

### First Embodiment

A semiconductor of this embodiment includes a GaN-based semiconductor layer having a surface with an angle of not less than 0 degree and not more than 5 degrees with respect to an m-plane or an a-plane, a first electrode provided on or above the surface and having a first end, and a second electrode provided on or above the surface to space apart from the first electrode, having a second end facing the first end, and disposed so that a direction of a segment connecting an arbitrary point of the first end and an arbitrary point of the second end is different from a c-axis direction of the GaN-based semiconductor layer.

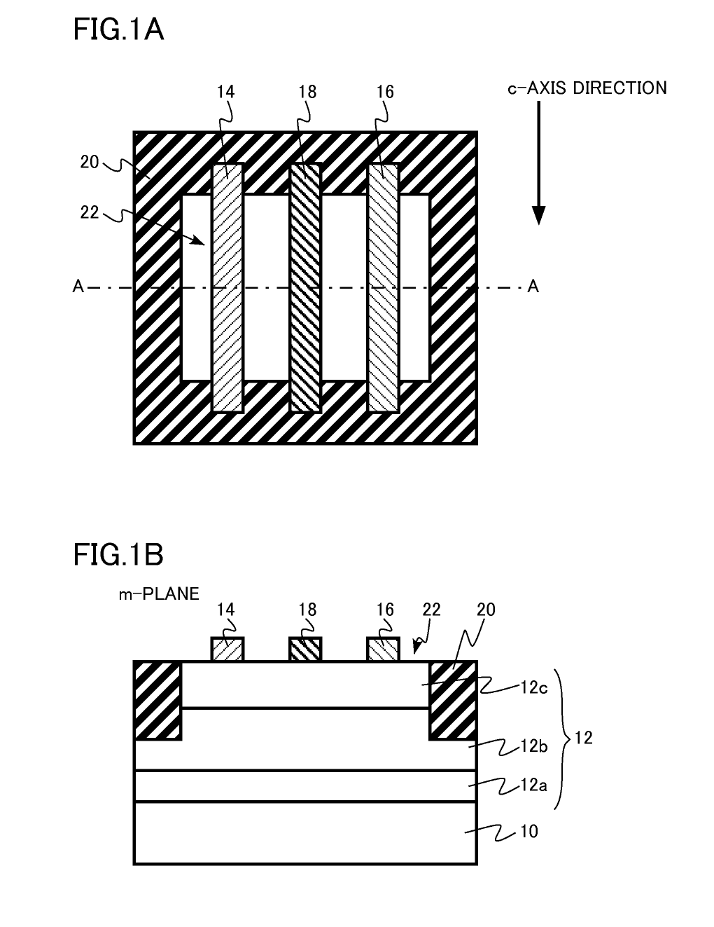

FIGS. 1A and 1B are schematic views of a semiconductor device of this embodiment. FIG. 1A is a schematic top view, and FIG. 1B is an A-A cross-sectional view of FIG. 1A. The semiconductor device of this embodiment is a high-electron-mobility transistor (HEMT) using a GaN-based semiconductor.

The semiconductor device of this embodiment includes a substrate 10, a GaN-based semiconductor layer 12, a source electrode (first electrode) 14, a drain electrode (second electrode) 16, a gate electrode (third electrode) 18, an element isolation region 20, and an active region (element region) 22.

The substrate 10 is GaN, for example. In addition to the GaN substrate 10, a gallium oxide substrate, an SiC substrate, an Si substrate, and a sapphire substrate may be used for example.

A GaN-based semiconductor layer 12 is provided on the substrate 10. A surface of the GaN-based semiconductor layer 12 has an angle of not less than 0 degree and not more than 5 degrees with respect to the m-plane or the a-plane. In terms of flatness of a surface and easiness for manufacturing, a surface of the GaN-based semiconductor layer preferably has an angle of not less than 0 degree and not more than 1 degree with respect to the m-plane or the a-plane and more preferably has an angle of not less than 0 degree and not more than 0.3 degrees.

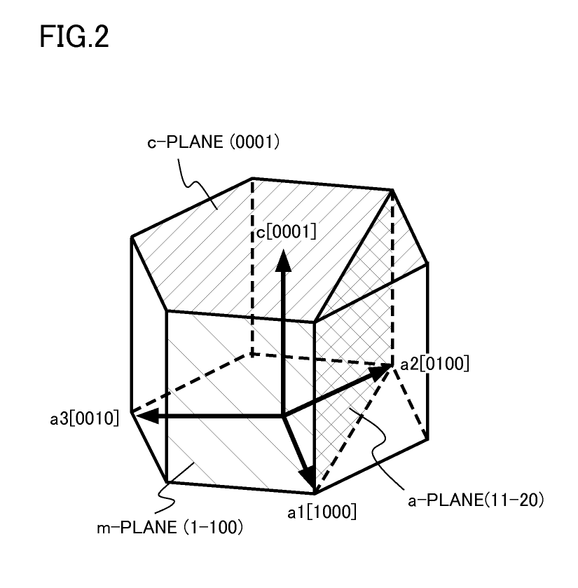

FIG. 2 is a view showing a crystal structure of the GaN-based semiconductor. The crystal structure of the GaN-based semiconductor may be approximated by a hexagonal system. A surface (top surface of a hexagonal column) in which a c axis along the axial direction of the hexagonal column is a normal line is a c-plane, that is, a (0001) plane. In the GaN-based semiconductor, a polarization direction follows the c axis. Thus, the c-plane is referred to as a polar face.

Meanwhile, the side surface (cylindrical surface) of the hexagonal column is the m-plane equivalent to a (1-100) plane, that is, a {1-100} plane. A surface passing through a pair of not-adjacent ridge lines is the a-plane equivalent to a (11-20) plane, that is, a {11-20} plane. The m-plane and the a-plane are referred to as a nonpolar plane.

Hereinafter, an example in which the surface of the GaN-based semiconductor layer 12 is the m-plane will be described. The following description can be applied to the case where the surface of the GaN-based semiconductor layer 12 is the a-plane which is the nonpolar plane as with the m-plane.

The GaN-based semiconductor layer 12 is constituted of a buffer layer 12a, a GaN layer 12b, and an AlGaN layer 12c provided in order from the substrate 10 side. A surface of the AlGaN layer 12c is the m-plane.

The buffer layer 12a has a function of alleviating lattice mismatch between the substrate 10 and the GaN-based semiconductor layer 12. The buffer layer 12a has a multilayer structure including AlGaN and GaN, for example.

The GaN layer 12b is a so-called operation layer (channel layer), and the AlGaN layer 12c is a so-called barrier layer (electron supply layer). The AlGaN layer 12c uses a semiconductor represented by the composition formula: AlₓGa₁₋ₓN (0<x<0.3).

The AlGaN layer 12c has a source electrode (first electrode) 14 on the surface. The AlGaN layer 12c has on its surface a drain electrode (second electrode) 16 spaced apart from the source electrode (first electrode) 14. A gate electrode (third electrode) 18 is provided between the source electrode (first electrode) 14 and the drain electrode (second electrode) 16.

The source electrode 14, the drain electrode 16, and the gate electrode 18 are metal electrodes, for example. The metal electrode is mainly composed of aluminum (Al), for example. The contact of the source electrode (first electrode) 14 and the drain electrode (second electrode) 16 with the GaN-based semiconductor layer 12 is preferably an ohmic contact.

The GaN-based semiconductor layer 12 has the element isolation region 20. The element isolation region 20 is, for example, an insulating body such as a silicon oxide film. The GaN-based semiconductor layer 12 surrounded by the element isolation region 20 is the active region (element region) 22.

The element isolation region 20 may be formed by, for example, introducing an impurity into the GaN-based semiconductor layer 12. The element isolation region 20 may have a mesa structure. Alternatively, the element isolation region 20 may be formed by patterning an insulating body on a surface of the GaN-based semiconductor layer 12.

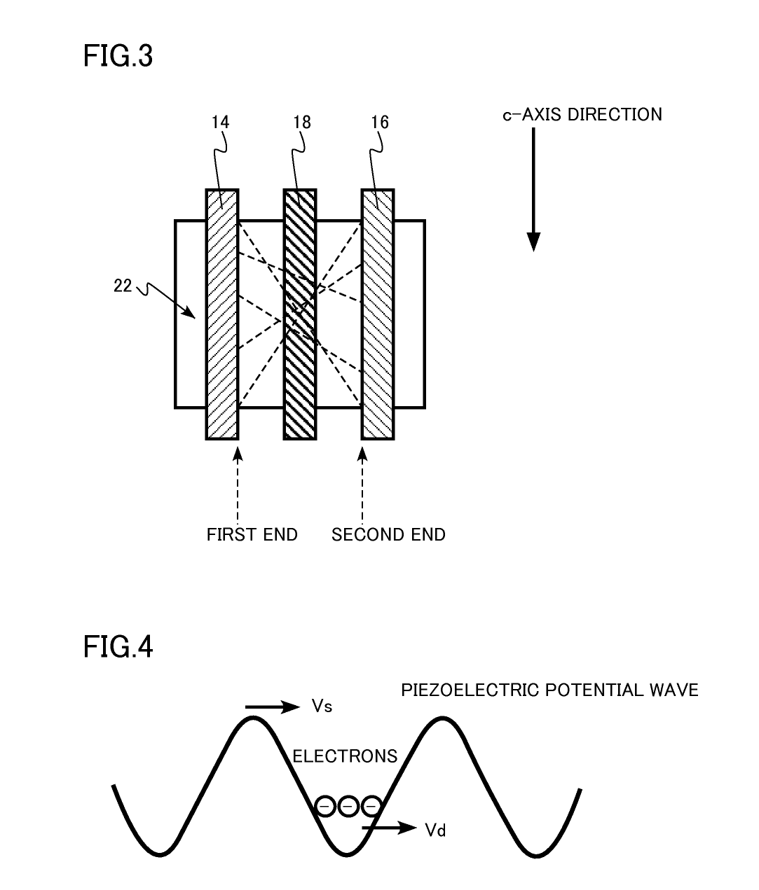

FIG. 3 is an explanatory view of electrode arrangement of the semiconductor device of this embodiment. A direction of a segment connecting an arbitrary point of a first end of the source electrode (first electrode) 14 that faces the drain electrode (second electrode) 16 and an arbitrary point of a second end of the drain electrode (second electrode) 16 that faces the source electrode (first electrode) 14 is different from the c-axis direction of the GaN-based semiconductor layer 12. FIG. 3 shows five dotted lines as examples of the segment.

In this embodiment, the first end and the second end are parallel to each other. The first end and the second end are parallel to the c-axis direction.

In this embodiment, the first end and the second end mean ends of a region where the source electrode (first electrode) 14 and the drain electrode (second electrode) 16 intersect with the active region (element region) 22. Namely, the first end and the second end mean ends of a region contributing to the operation of the device.

Next, an example of a method of manufacturing the semiconductor device of this embodiment will be explained. The following description of the manufacturing method refers to FIG. 1.

For example, a GaN substrate whose surface is the (1-100) plane as the m-plane is provided. The GaN substrate is an example of the substrate 10.

In the formation of the GaN substrate, an ingot of bulk GaN is made by a liquid phase growth process such as a sodium flux process or a melt-growth method such as an ammonothermal process and then diced so that the m-plane is the surface. The buffer layer 12a, the GaN layer 12b, and the AlGaN layer 12c are continuously film-formed by an epitaxial growth method in a growth mode parallel to the (1-100) plane, and the GaN-based semiconductor layer 12 is formed.

In addition to the GaN substrate 10, a gallium oxide substrate, an SiC substrate, an Si substrate, and a sapphire substrate may be used for example. When the SiC substrate or the sapphire substrate is used, in order to epitaxially grow, on the substrate 10, the GaN-based semiconductor layer 12 whose surface is the m-plane, the plane direction of the surface of the SiC substrate or the sapphire substrate is preferably the m-plane. However, since there is a case where an a-plane GaN is grown on an r-plane sapphire substrate, a surface for growth may not be always the m-plane according to growth conditions.

The GaN-based semiconductor layer 12 is formed by, for example, an MOCVD (metal-organic chemical vapor deposition) apparatus, using a TMG (trimethylgallium) gas or a TMA (trimethylaluminum) gas as a III group element source, a nitrogen gas or a hydrogen gas as a carrier gas, and an ammonia (NH₃) gas as a V group element source.

In the formation of the buffer layer 12a, an AlGaN layer having a thickness of 9 nm and a GaN layer having a thickness of 9 nm are alternately staked on a GaN substrate, for example, to form an AlGaN/GaN structure having a thickness of 200 nm. The method of buffer layer formation includes various methods, and, for example, the thickness of each layer is changed to be sequentially increased or reduced, several hundred layers are stacked at fixed intervals as described above, or layers having different thickness are inserted at fixed intervals. A suitable method for suppressing the lattice mismatch may be selected from among those methods.

As the GaN layer 12b, GaN having a thickness of 1500 nm is stacked on the buffer layer 12a, for example. As the AlGaN layer 12c, AlGaN having a thickness of 30 nm as an electron supply layer is formed on the GaN layer 12b, for example. In order to generate two-dimensional electrons in the AlGaN layer 12c, the AlGaN layer 12c is doped with Si of approximately 1×10¹⁸ atoms/cm³ as an impurity, for example.

After the formation of the GaN-based semiconductor layer 12, a photoresist having an opening in a region where the source electrode 14 and the drain electrode 16 are to be formed is formed by a well-known photolithography technique. An electrode material used as the material of the source electrode 14 and the drain electrode 16 is sputtered on an upper surface of the AlGaN layer 12c.

After that, the photoresist is removed, whereby an unnecessary portion of the electrode material (a portion other than the source electrode 14 and the drain electrode 16) is lifted off along with the photoresist. The source electrode 14 and the drain electrode 16 are formed by those processes.

After the formation of the source electrode 14 and the drain electrode 16, annealing treatment is performed. The source electrode 14 and the drain electrode 16 are electrically connected with the AlGaN layer 12c by the annealing treatment.

Next, a photoresist having an opening in a region where the gate electrode 18 is to be formed is formed by a well-known photolithography technique. An electrode material used as the material of the gate electrode 18 is sputtered on the upper surface of the AlGaN layer 12c.

After that, the photoresist is removed, whereby an unnecessary portion of the electrode material (a portion other than the gate electrode 18) is lifted off along with the photoresist. The gate electrode 18 is formed by those processes.

Prior to the formation of the gate electrode 18, a dielectric body as a gate insulating film may be formed on a surface on which the source electrode 14 and the drain electrode 16 are formed, according to need. The dielectric body may be formed of a material capable of obtaining desired gate electrode characteristics, such as SiO₂, SiN, and AlN. The dielectric body is deposited by, for example, a PECVD (Plasma Enhanced Chemical Vapor Deposition) method, an LPCVD (Low pressure chemical vapor deposition) method, or an ECR (Electron Cyclotron Resonance) sputtering method.

The semiconductor device having a structure shown in FIG. 1 can be manufactured by the above manufacturing method.

Hereinafter, the operation and effect of the semiconductor device of this embodiment will be described. FIGS. 4 and 5 are explanatory views of the semiconductor device of this embodiment.

In a piezoelectric semiconductor such as GaN, an ultrasonic wave flux is locally generated in a portion of a sample, and a so-called acoustic domain is formed. This is a phenomenon occurring when a source electrode, a gate electrode, and a drain electrode are formed so that an electric field parallel to a polarization direction is applied to a surface of the m-plane or the a-plane.

Thus, when an electrode pattern vertical to the c-axis direction is formed, the drift velocity of electrons is generally higher than the acoustic velocity in a GaN semiconductor, and therefore, a resonance phenomenon due to acoustic wave amplification may occur between the source electrode and the drain electrode in which the electric field is formed. When the resonance phenomenon occurs, the electrons are trapped at the bottom of a piezoelectric potential wave, and current saturation occurs.

The current saturation occurs at a place where the acoustic wave amplification occurs, and resistance in this region is apparently increased. Accordingly, in such a state that a constant voltage is applied to a sample, the electric field is concentrated on this region, so that a high field domain is formed. Namely, the electric field concentration occurs along with the resonance phenomenon, and if this state continues, the sample may be finally broken down, or crystal itself may be broken.

The resonance phenomenon due to the acoustic wave amplification occurs due to that a thermal noise ultrasonic wave in crystal is locally amplified in the sample and can be described as follows. When an ultrasonic wave is propagated in a piezoelectric semiconductor, a sound wave forms a potential wave shown in FIG. 4 at a bottom of a conduction band for piezoelectricity. Then, electrons are captured in the potential valley. The electric field is applied in a direction the same as the propagating direction of the ultrasonic wave to accelerate the electrons, and when the drift velocity (Vd in FIG. 4) of the electrons exceeds the propagation velocity (acoustic velocity: Vs in FIG. 4) of the potential wave, the energy of the electrons flows to an acoustic wave system, and the ultrasonic wave is amplified, whereby the potential valley becomes deep. When the piezoelectric constants of GaN are compared, there is a relation of |e33|>|e15|. Accordingly, when the electric field having the same size is applied, a larger stress is generated in the case of applying the electric field to a spontaneous polarization in parallel, compared with the case of applying the electric field vertically. When the electric field is applied to the spontaneous polarization in parallel, distortion of expansion and contraction occurs and involves a large volume change. Meanwhile, when the electric field is applied to the spontaneous polarization vertically, shear strain occurs, the volume change is relatively small. A deformation potential is proportional to the volume change. Accordingly, a potential change of a larger amplitude occurs in the case of applying the electric field to the spontaneous polarization in parallel.

When the depth of the valley is smaller than the thermal energy of the electrons, the electrons can be freely emitted from this valley. Accordingly, electric conduction is not affected, and an ohmic property is maintained. However, the ultrasonic wave is amplified more and more, and when the depth of the valley becomes sufficiently larger than the thermal energy, the electrons can no longer be emitted from this valley and move at the acoustic velocity along with the ultrasonic wave.

Current saturation thus occurs. The sample has some sort of nonuniformity, and when ultrasonic wave amplification more easily occurs in a certain region than in other portions, the current saturation occurs only in this region to apparently increase the electrical resistance in this region. Accordingly, in such a state that a constant voltage is applied to the sample, the electric field is concentrated on this region, so that a high field domain is formed. Namely, the electric field concentration occurs along with the resonance phenomenon, and if this state continues, the sample may be finally broken down, or crystal itself may be broken.

FIG. 5 shows a relation between the electric field and the drift velocity of electrons in various semiconductors. In a standard circuit dimension in which a distance between a source and a drain is approximately 20 μm, the electric field of approximately 100 kV/cm is formed. The drift velocity of electrons is 2×10⁷ cm/s. The acoustic velocity of GaN is 6.6×10⁵ cm/s, and thus the drift velocity of electrons is higher than the acoustic velocity. Thus, it is found that the resonance phenomenon due to the ultrasonic wave amplification may occur in the GaN-based semiconductor.

When the source electrode and the drain electrode are parallel to each other on the c-plane, the above phenomenon occurs in any direction.

As described above, even when the GaN-based semiconductor uses the structure using a crystal plane, which is a nonpolar plane exhibiting no piezoelectricity, such as the m-plane and the a-plane or uses the structure using the c-plane which is a polar plane, it is difficult to use the high mobility in a structure giving no consideration to the features of the piezoelectric semiconductor.

In this embodiment, the direction of the segment connecting an arbitrary point of the first end of the source electrode (first electrode) 14 that faces the drain electrode (second electrode) 16 and an arbitrary point of the second end of the drain electrode (second electrode) 16 that faces the source electrode (first electrode) 14 is different from the c-axis direction of the GaN-based semiconductor layer 12. Thus, the direction of the electric field applied to between the source electrode (first electrode) 14 and the drain electrode (second electrode) 16 is different from the c-axis direction. Accordingly, the ultrasonic wave amplification is less likely to occur, and the resonance phenomenon due to the ultrasonic sound amplification hardly occurs.

In this embodiment, in terms of suppressing the ultrasonic wave amplification, the gate electrode 18 or the end thereof may not be parallel to the first end or the second end.

Hereinabove, according to this embodiment, since the resonance phenomenon due to the ultrasonic wave amplification hardly occurs, a semiconductor device with enhanced reliability is realized.

### Second Embodiment

A semiconductor device of this embodiment is similar to the semiconductor device of the first embodiment, except that a first end and a second end are not parallel to a c-axis direction. Accordingly, the description of the contents overlapped with those of the first embodiment is omitted.

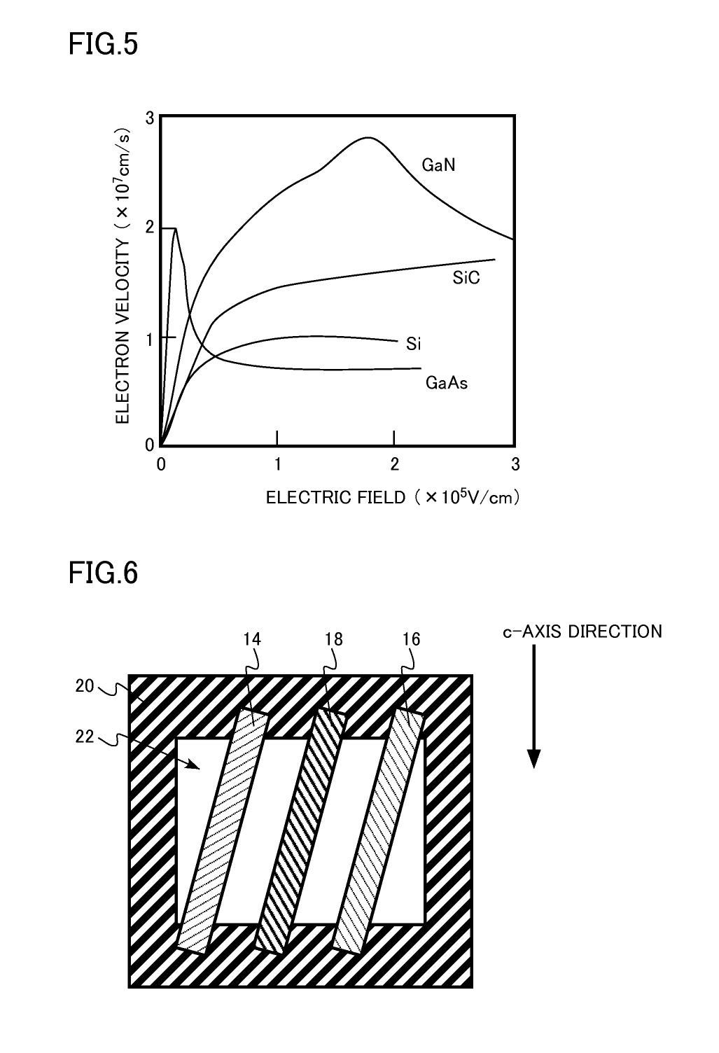

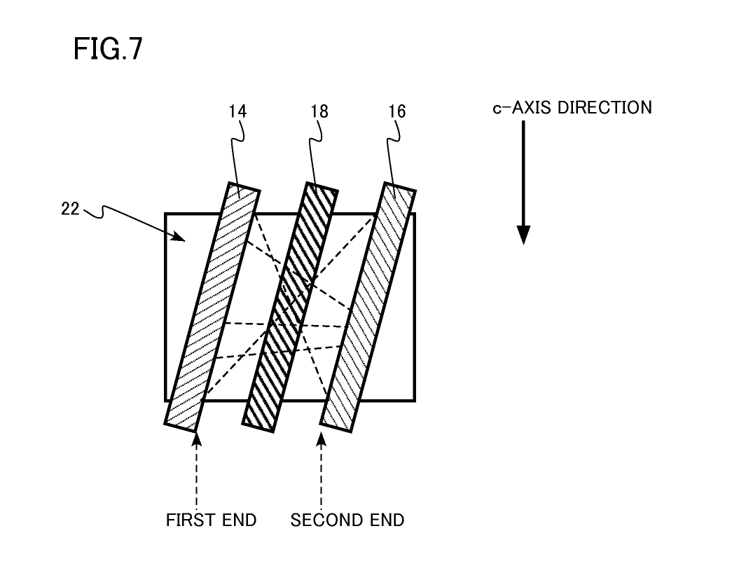

FIG. 6 is a schematic top view of the semiconductor device of this embodiment. FIG. 7 is an explanatory view of electrode arrangement of the semiconductor device of this embodiment. A direction of a segment connecting an arbitrary point of a first end of a source electrode (first electrode) 14 that faces a drain electrode (second electrode) 16 and an arbitrary point of a second end of the drain electrode (second electrode) 16 that faces the source electrode (first electrode) 14 is different from the c-axis direction of a GaN-based semiconductor layer 12. FIG. 7 shows five dotted lines as examples of the segment.

In this embodiment, the first end and the second end are parallel to each other. The first end and the second end are not parallel to the c-axis direction. Namely, the first end and the second end are skewed to the c-axis direction.

In this embodiment, the direction of the electric field applied to between the source electrode (first electrode) 14 and the drain electrode (second electrode) 16 is different from the c-axis direction. Accordingly, the ultrasonic wave amplification is less likely to occur, and the resonance phenomenon due to the ultrasonic wave amplification hardly occurs.

Hereinabove, according to this embodiment, since the resonance phenomenon due to the ultrasonic wave amplification hardly occurs, a transistor device with enhanced reliability is realized.

### Third Embodiment

A semiconductor device of this embodiment is similar to the semiconductor device of the first embodiment, except that the semiconductor device of this embodiment is a diode having no third electrode. Accordingly, the description of the contents overlapped with those of the first embodiment is omitted.

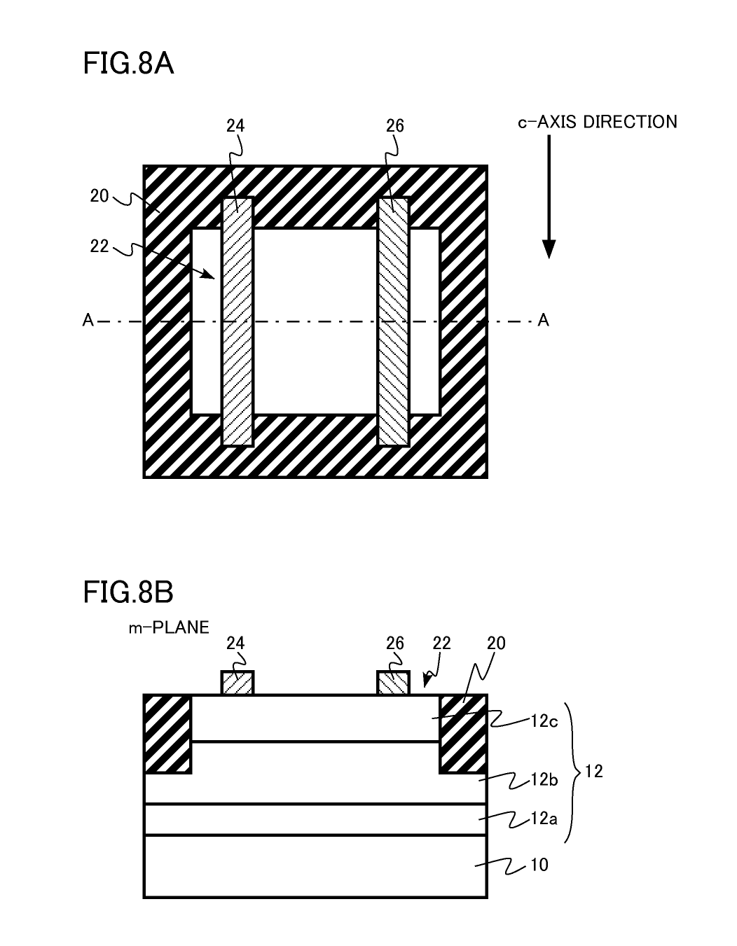

FIGS. 8A and 8B are schematic diagrams of the semiconductor device of this embodiment. FIG. 8A is a schematic top view, and FIG. 8B is an A-A cross-sectional view of FIG. 8A. The semiconductor device of this embodiment is a schottky barrier diode (SBT) using a GaN-based semiconductor.

The semiconductor device of this embodiment includes a substrate 10, a GaN-based semiconductor layer 12, an anode electrode (first electrode) 24, a cathode electrode (second electrode) 26, an element isolation region 20, and an active region (element region) 22. One of the contact between the anode electrode (first electrode) 24 and the GaN-based semiconductor layer 12 and the contact between the cathode electrode (second electrode) 26 and the GaN-based semiconductor layer 12 is a schottky contact, and the other is the ohmic contact.

A direction of a segment connecting an arbitrary point of a first end of the anode electrode (first electrode) 24 that faces the cathode electrode (second electrode) 26 and an arbitrary point of a second end of the cathode electrode (second electrode) 26 that faces the anode electrode (first electrode) 24 does not coincide with a c-axis direction of the GaN-based semiconductor layer 12.

In this embodiment, the first end and the second end are parallel to each other and parallel to the c-axis direction.

In this embodiment, a direction of the electric field applied to between the anode electrode (first electrode) 24 and the cathode electrode (second electrode) 26 is different from the c-axis direction. Accordingly, the ultrasonic wave amplification is less likely to occur, and the resonance phenomenon due to the ultrasonic wave amplification hardly occurs.

Hereinabove, according to this embodiment, since the resonance phenomenon due to the ultrasonic wave amplification hardly occurs, a diode with enhanced reliability is realized.

### Fourth Embodiment

A semiconductor device of this embodiment is similar to the semiconductor device of the third embodiment, except that a first end and a second end are not parallel to a c-axis direction. Accordingly, the description of the contents overlapped with those of the third embodiment is omitted.

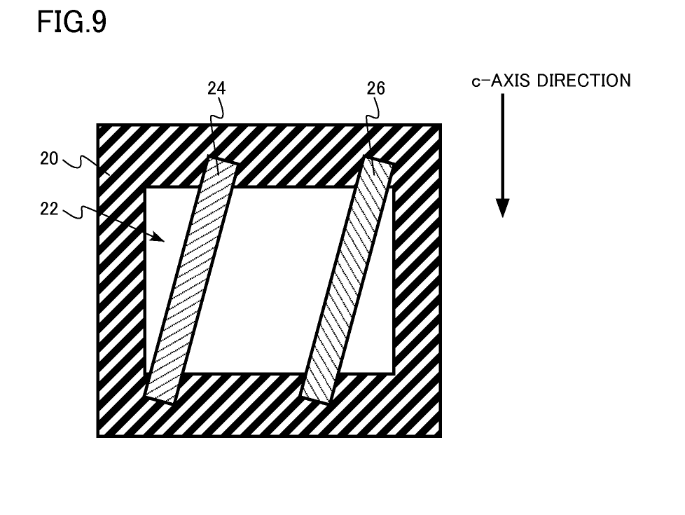

FIG. 9 is a schematic top view of the semiconductor device of this embodiment. A direction of a segment connecting an arbitrary point of a first end of an anode electrode (first electrode) 24 that faces a cathode electrode (second electrode) 26 and an arbitrary point of a second end of the cathode electrode (second electrode) 26 that faces the anode electrode (first electrode) 24 is different from a c-axis direction of a GaN-based semiconductor layer 12.

In this embodiment, the first end and the second end are parallel to each other and are not parallel to the c-axis direction.

In this embodiment, a direction of the electric field applied to between the anode electrode (first electrode) 24 and the cathode electrode (second electrode) 26 is different from the c-axis direction. Accordingly, the ultrasonic wave amplification is less likely to occur, and the resonance phenomenon due to the ultrasonic wave amplification hardly occurs.

Hereinabove, according to this embodiment, since the resonance phenomenon due to the ultrasonic wave amplification hardly occurs, a diode with enhanced reliability is realized.

### Fifth Embodiment

A semiconductor device of this embodiment is similar to the semiconductor device of the first embodiment, except that a gate electrode (third electrode) has a recess structure. Accordingly, the description of the contents overlapped with those of the first embodiment is omitted.

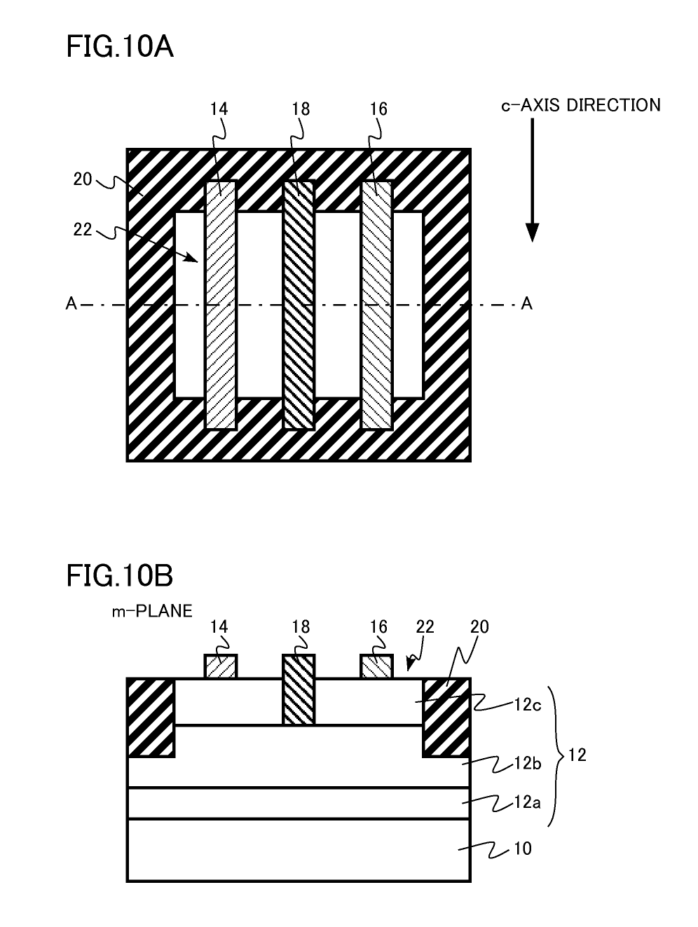

FIGS. 10A and 10B are schematic diagrams of the semiconductor device of this embodiment. FIG. 10A is a schematic top view, and FIG. 10B is an A-A cross-sectional view of FIG. 10A.

The semiconductor device of this embodiment has the recess structure in which a gate electrode (third electrode) 18 is provided in a GaN-based semiconductor layer 12. A lower end of the gate electrode (third electrode) 18 reaches a GaN layer 12b, for example.

When the semiconductor of this embodiment is manufactured, a photoresist having an opening in a region where the gate electrode 18 is to be formed is formed by a well-known photolithography technique. After that, an AlGaN layer 12c is selectively etched. Then, an electrode material used as a material of the gate electrode 18 is sputtered. Other processes are similar to those of the first embodiment.

Hereinabove, according to this embodiment, a transistor which improves the reliability as in the first embodiment and is easily rendered normally-off is realized.

The semiconductor device of this embodiment may have a structure in which the lower end of the gate electrode (third electrode) 18 does not reach the GaN layer 12b.

### Sixth Embodiment

A semiconductor device of this embodiment is similar to the semiconductor device of the first embodiment, except that a GaN-based semiconductor layer 12 includes a p-type GaN layer. Accordingly, the description of the contents overlapped with those of the first embodiment is omitted.

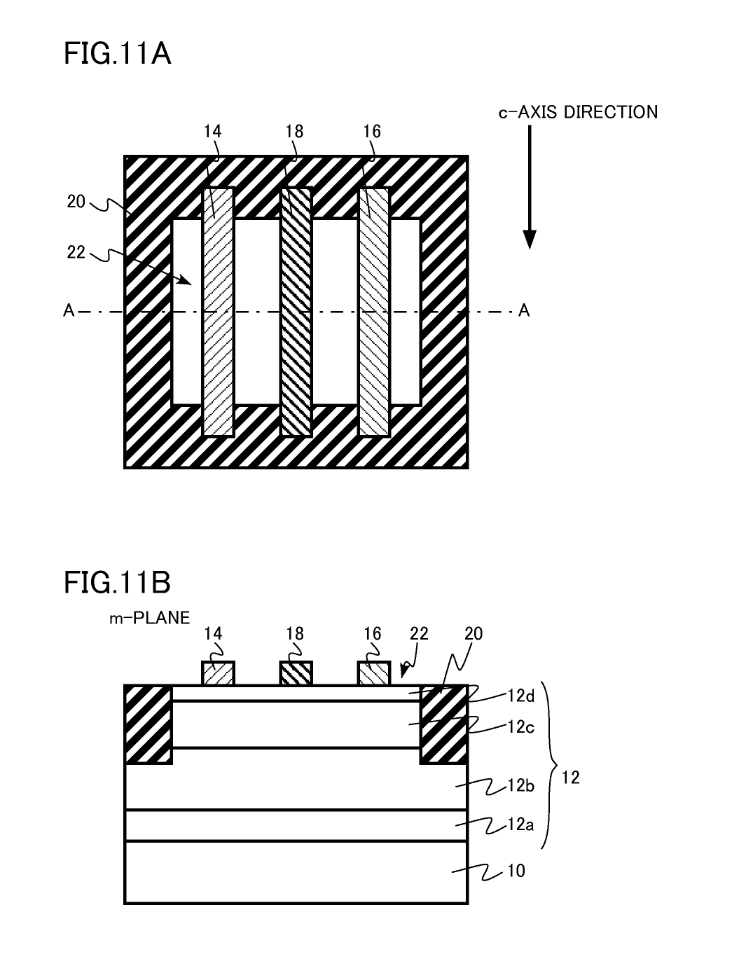

FIGS. 11A and 11B are schematic diagrams of the semiconductor device of this embodiment. FIG. 11A is a schematic top view, and FIG. 11B is an A-A cross-sectional view of FIG. 11A.

In the semiconductor device of this embodiment, the GaN-based semiconductor layer 12 is constituted of a buffer layer 12a, a GaN layer 12b, an AlGaN layer 12c, and a p-type GaN layer 12d provided in order from the substrate 10 side. The p-type GaN layer 12d is doped with Mg (magnesium) of approximately 1×10²⁰ atoms/cm³ as a p-type impurity.

The p-type GaN layer 12d functions as a surface protective layer of the AlGaN layer 12c and stabilizes the characteristics of the semiconductor device.

Hereinabove, according to this embodiment, a transistor which improves the reliability as in the first embodiment and has stable characteristics is realized.

### Seventh Embodiment

The semiconductor device of this embodiment includes a GaN-based semiconductor layer, a first electrode provided on a surface of the GaN-based semiconductor layer and having a first end, and a second electrode provided on the surface of the GaN-based semiconductor layer to space apart from the first electrode and having a second end facing the first end and not parallel to the first end. Namely, the first end of the first electrode and the second end of the second electrode are not parallel.

A semiconductor device of this embodiment is similar to the semiconductor device of the first embodiment, except that a surface of a GaN-based semiconductor layer is a c-plane, and the arrangement pattern of electrodes is different. Accordingly, the description of the contents overlapped with those of the first embodiment is omitted.

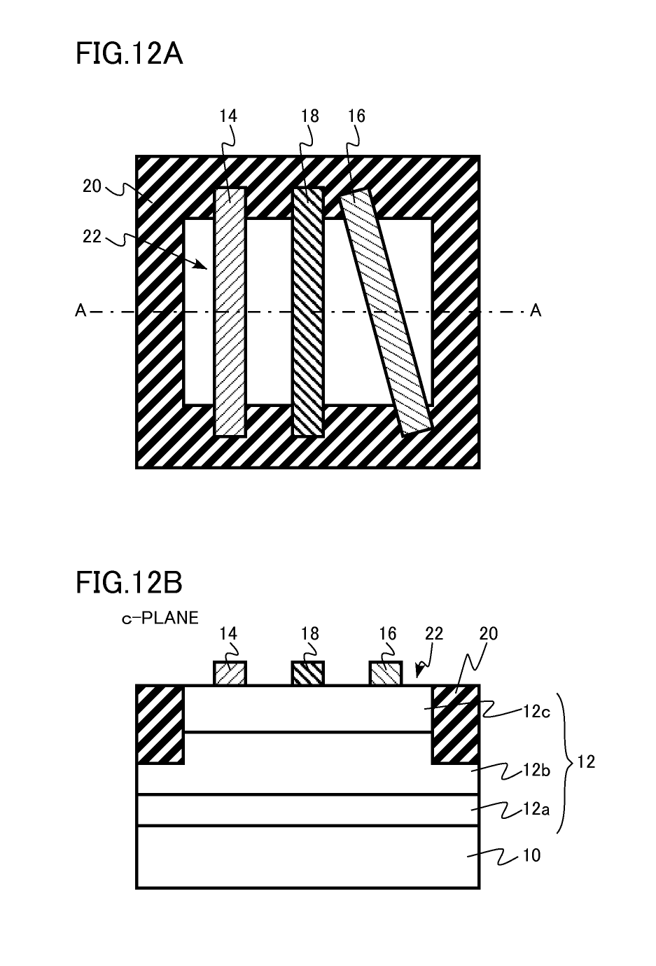

FIGS. 12A and 12B are schematic diagrams of the semiconductor device of this embodiment. FIG. 12A is a schematic top view, and FIG. 12B is an A-A cross-sectional view of FIG. 12A. The semiconductor device of this embodiment is a high-electron-mobility transistor (HEMT) using a GaN-based semiconductor.

A surface of the GaN-based semiconductor layer 12 has an angle of not less than 0 degree and not more than 5 degrees with respect to the c-plane, and in terms of flatness of a surface and easiness for manufacturing, the surface of the GaN-based semiconductor layer preferably has an angle of not less than 0 degree and not more than 1 degree with respect to the c-plane, and more preferably has an angle of not less than 0 degree and not more than 0.3 degrees.

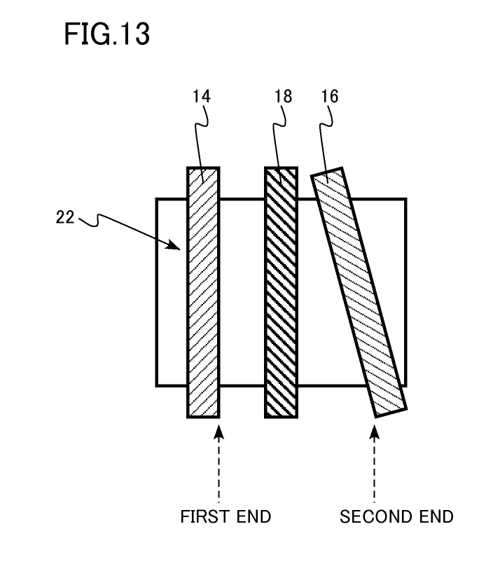

FIG. 13 is an explanatory view of the electrode arrangement of the semiconductor device of this embodiment. A first end of a source electrode (first electrode) 14 that faces a drain electrode (second electrode) 16 and a second end of the drain electrode (second electrode) 16 that faces the source electrode (first electrode) 14 are not parallel, and the first end and the second end are linear.

In this embodiment, the first end and the second end mean ends of a region where the source electrode (first electrode) 14 and the drain electrode (second electrode) 16 intersect with an active region (element region) 22. Namely, the first end and the second end mean ends of a region contributing to the operation of the device.

The ultrasonic wave amplification is the resonance phenomenon. Thus, when the first end and the second end are not parallel, that is, when a distance is not fixed, a phase of a reflected wave under the electric field does not coincide even if a surface is the c-plane, the resonance phenomenon is less likely to occur. Accordingly, insulation breakdown due to the electric field concentration and destruction of crystal are less likely to occur.

Hereinabove, according to this embodiment, since the resonance phenomenon due to the ultrasonic wave amplification hardly occurs, a transistor device with enhanced reliability is realized.

The shape of the gate electrode (third electrode) 18 is not limited especially. The electrode arrangement pattern of this embodiment may be applied onto an m-plane or an a-plane, instead of the c-plane.

The contact of the source electrode (first electrode) 14 and the drain electrode (second electrode) 16 with the GaN-based semiconductor layer 12 is preferably the ohmic contact.

### Eighth Embodiment

A semiconductor device of this embodiment is similar to the semiconductor device of the seventh embodiment, except that the first end and the second end have a step-like shape. Accordingly, the description of the contents overlapped with those of the seventh embodiment is omitted.

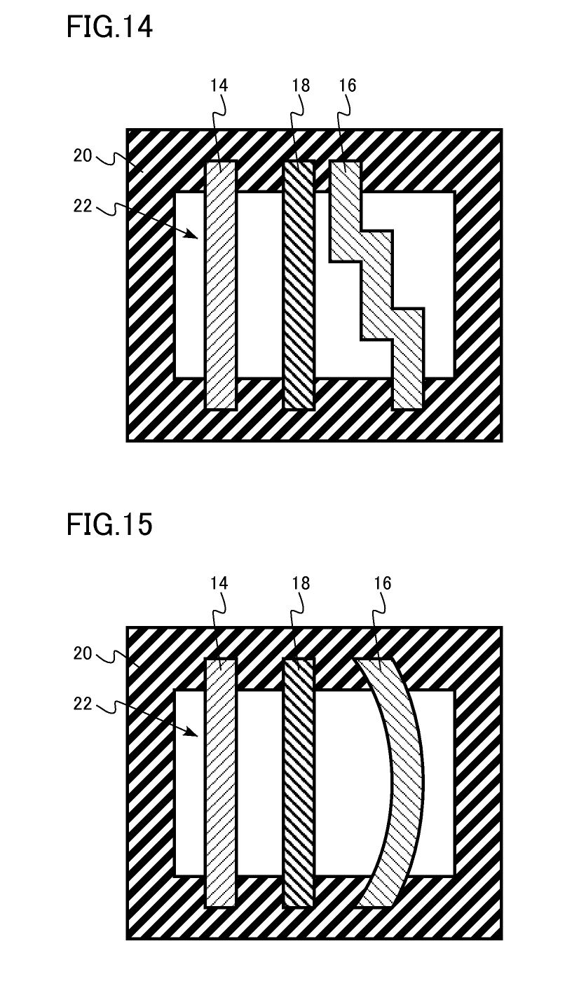

FIG. 14 is a schematic top view of the semiconductor device of this embodiment.

A second end of a drain electrode (second electrode) 16 that faces a source electrode (first electrode) 14 has a step-like shape. According to this constitution, in this embodiment, a first end of the source electrode (first electrode) 14 that faces the drain electrode (second electrode) 16 and the second end of the drain electrode (second electrode) 16 that faces the source electrode (first electrode) 14 are not parallel.

Hereinabove, according to this embodiment, since the resonance phenomenon due to the ultrasonic wave amplification hardly occurs, a transistor device with enhanced reliability is realized.

Instead of the second end, the first end may have a step-like shape. Both the first end and the second end may have a step-like shape. A shape of a gate electrode (third electrode) 18 is not limited especially. The electrode arrangement pattern of this embodiment may be applied onto an m-plane or an a-plane, instead of a c-plane.

### Ninth Embodiment

A semiconductor device of this embodiment is similar to the semiconductor device of the seventh embodiment, except that the first end or the second end is curved. Accordingly, the description of the contents overlapped with those of the seventh embodiment is omitted.

FIG. 15 is a schematic top view of a semiconductor device of this embodiment.

A second end of a drain electrode (second electrode) 16 that faces a source electrode (first electrode) 14 is curved. According to this constitution, in this embodiment, a first end of the source electrode (first electrode) 14 that faces the drain electrode (second electrode) 16 and the second end of the drain electrode (second electrode) 16 that faces the source electrode (first electrode) 14 are not parallel.

Hereinabove, according to this embodiment, since the resonance phenomenon due to the ultrasonic wave amplification hardly occurs, a transistor device with enhanced reliability is realized.

Instead of the second end, the first end may be curved. Both the first end and the second end may be curved. A shape of a gate electrode (third electrode) 18 is not limited especially. The electrode arrangement pattern of this embodiment may be applied onto an m-plane or an a-plane, instead of a c-plane.

### Tenth Embodiment

A semiconductor device of this embodiment is similar to the semiconductor device of the seventh embodiment, except that the semiconductor device of this embodiment is a diode having no third electrode. Accordingly, the description of the contents overlapped with those of the seventh embodiment is omitted.

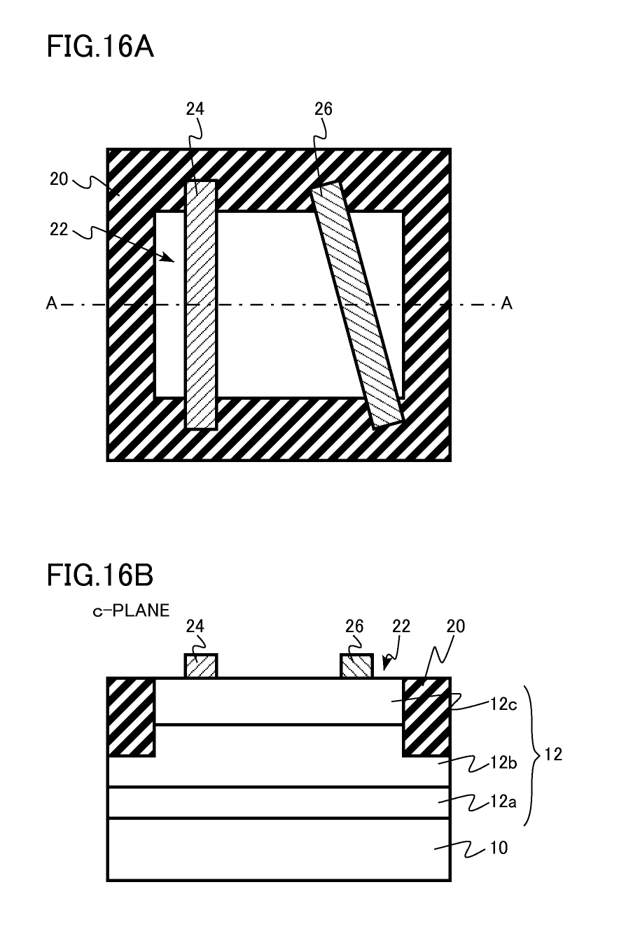

FIGS. 16A and 16B are schematic diagrams of the semiconductor device of this embodiment. FIG. 16A is a schematic top view, and FIG. 16B is an A-A cross-sectional view of FIG. 16A. The semiconductor device of this embodiment is a schottky barrier diode (SBT) using a GaN-based semiconductor.

The semiconductor device of this embodiment includes a substrate 10, a GaN-based semiconductor layer 12, an anode electrode (first electrode) 24, a cathode electrode (second electrode) 26, an element isolation region 20, and an active region (element region) 22. One of the contact between the anode electrode (first electrode) 24 and the GaN-based semiconductor layer 12 and the contact between the cathode electrode (second electrode) 26 and the GaN-based semiconductor layer 12 is the schottky contact, and the other is the ohmic contact.

A first end of the anode electrode (first electrode) 24 that faces the cathode electrode (second electrode) 26 and a second end of the cathode electrode (second electrode) 26 that faces the anode electrode (first electrode) 24 are not parallel. The first end and the second end are linear.

In this embodiment, the end of the anode electrode (first electrode) 24 and the end of the cathode electrode (second electrode) 26 are not parallel. Accordingly, the ultrasonic wave amplification is less likely to occur, and the resonance phenomenon due to the ultrasonic wave amplification hardly occurs.

Hereinabove, according to this embodiment, since the resonance phenomenon due to the ultrasonic wave amplification hardly occurs, a diode with enhanced reliability is realized.

### Eleventh Embodiment

A semiconductor device of this embodiment is similar to the semiconductor device of the tenth embodiment, except that a first end or a second end has a step-like shape. Accordingly, the description of the contents overlapped with those of the tenth embodiment is omitted.

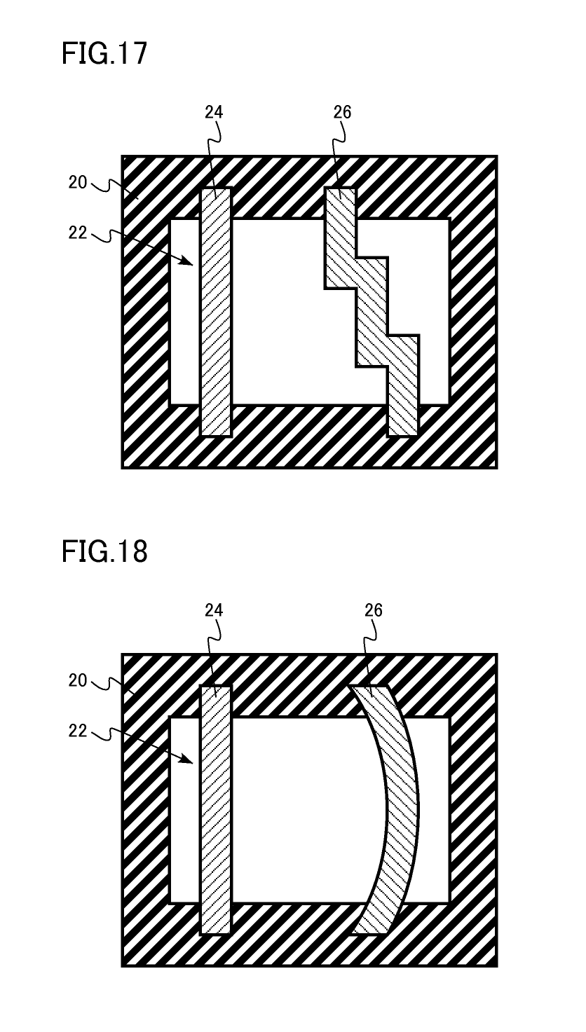

FIG. 17 is a schematic top view of the semiconductor device of this embodiment.

A first end of an anode electrode (first electrode) 24 that faces a cathode electrode (second electrode) 26 and a second end of the cathode electrode (second electrode) 26 that faces the anode electrode (first electrode) 24 are not parallel. The first end and the second end have a step-like shape.

Hereinabove, according to this embodiment, since the resonance phenomenon due to the ultrasonic wave amplification hardly occurs, a diode with enhanced reliability is realized.

Instead of the second end, the first end may have a step-like shape. Both the first end and the second end may have a step-like shape. The electrode arrangement pattern of this embodiment may be applied onto an m-plane or an a-plane, instead of a c-plane.

### Twelfth Embodiment

A semiconductor device of this embodiment is similar to the semiconductor device of the tenth embodiment, except that a first end or a second end is curved. Accordingly, the description of the contents overlapped with those of the tenth embodiment is omitted.

FIG. 18 is a schematic top view of the semiconductor device of this embodiment.

A first end of an anode electrode (first electrode) 24 that faces a cathode electrode (second electrode) 26 and a second end of the cathode electrode (second electrode) 26 that faces the anode electrode (first electrode) 24 are not parallel. The first end and the second end are curved.

Hereinabove, according to this embodiment, since the resonance phenomenon due to the ultrasonic wave amplification hardly occurs, a diode with enhanced reliability is realized.

Instead of the second end, the first end may be curved. Both the first end and the second end may be curved. The electrode arrangement pattern of this embodiment maybe applied onto an m-plane or an a-plane, instead of a c-plane.

### Thirteenth Embodiment

A semiconductor device of this embodiment is similar to the semiconductor device of the seventh embodiment, except that a surface of a GaN-based semiconductor layer has an angle of not less than 0 degree and not more than 5 degrees with respect to an m-plane or an a-plane. Accordingly, the description of the contents overlapped with those of the seventh embodiment is omitted.

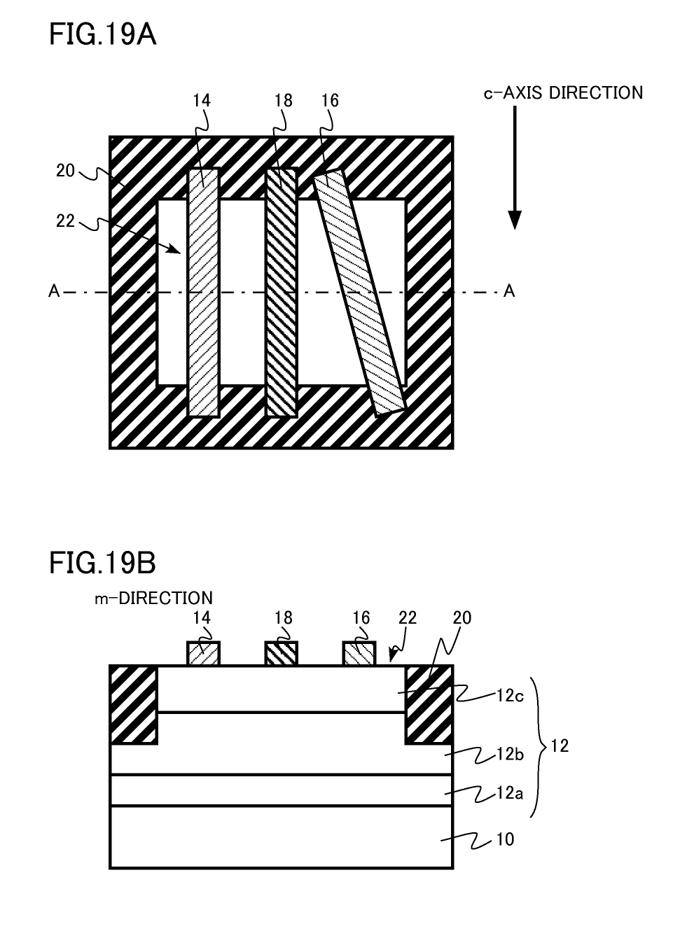

FIGS. 19A and 19B are schematic diagrams of the semiconductor device of this embodiment. FIG. 19A is a schematic top view, and FIG. 19B is an A-A cross-sectional view of FIG. 19A.

A first end of a source electrode (first electrode) 14 that faces a drain electrode (second electrode) 16 and a second end of the drain electrode (second electrode) 16 that faces the source electrode (first electrode) 14 are not parallel, and the first end and the second end are linear.

Hereinabove, according to this embodiment, since the resonance phenomenon due to the ultrasonic wave amplification hardly occurs, a transistor device with enhanced reliability is realized. The direction of the electric field applied to the source electrode (first electrode) 14 and the drain electrode (second electrode) 16 is different from a c-axis direction. Accordingly, since the resonance phenomenon due to the ultrasonic wave amplification more hardly occurs, the reliability of the transistor device is further enhanced.

### Fourteenth Embodiment

A semiconductor device of this embodiment includes a GaN-based semiconductor layer, a first electrode provided on a surface of the GaN-based semiconductor layer and having a curved first end, and a second electrode provided on the surface of the GaN-based semiconductor layer to space apart from the first electrode and having a curved second end facing the first end.

The semiconductor device of this embodiment is similar to the semiconductor device of the first embodiment, except that a surface of a GaN-based semiconductor layer is a c-plane, and an electrode arrangement pattern is different. Accordingly, the description of the contents overlapped with those of the first embodiment is omitted.

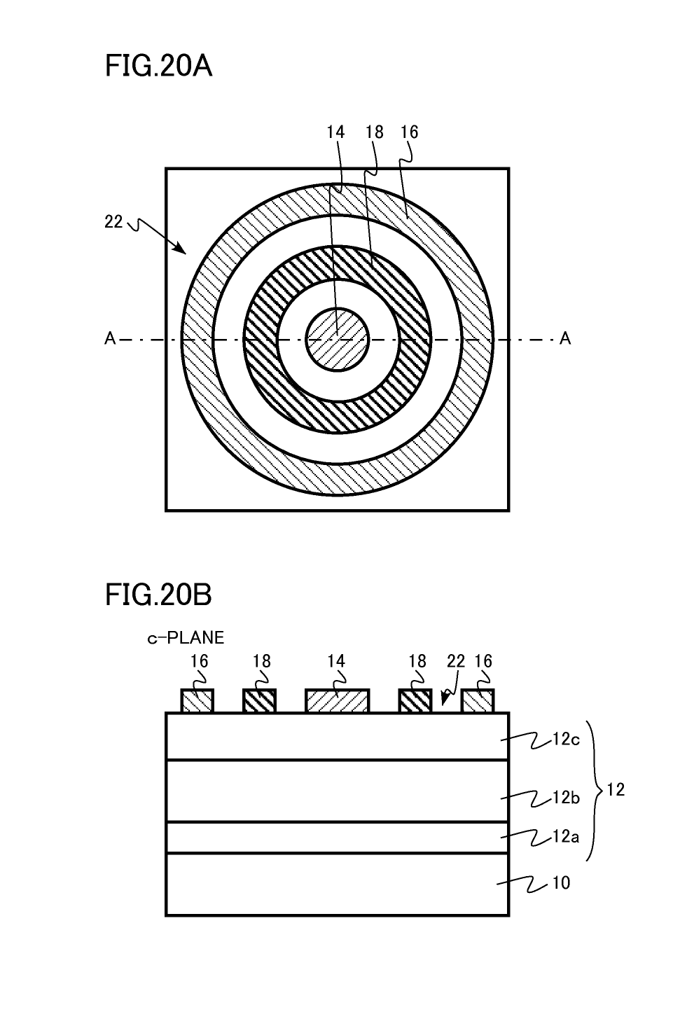

FIGS. 20A and 20B are schematic diagrams of the semiconductor device of this embodiment. FIG. 20A is a schematic top view, and FIG. 20B is an A-A cross-sectional view of FIG. 20A. The semiconductor device of this embodiment is a high-electron-mobility transistor (HEMT) using a GaN-based semiconductor.

A surface of the GaN-based semiconductor layer 12 has an angle of not less than 0 degree and not more than 5 degrees with respect to the c-plane, and in terms of flatness of a surface and easiness for manufacturing, the surface of the GaN-based semiconductor layer preferably has an angle of not less than 0 degree and not more than 1 degree with respect to the c-plane, and more preferably has an angle of not less than 0 degree and not more than 0.3 degrees.

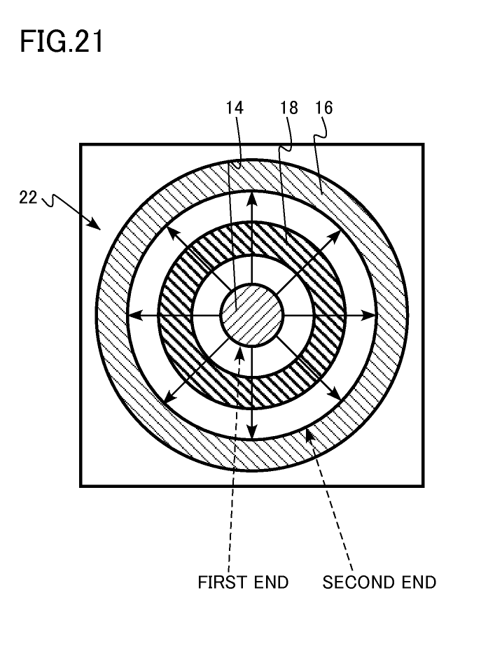

FIG. 21 is an explanatory view of electrode arrangement of the semiconductor device of this embodiment. A first end of a source electrode (first electrode) 14 that faces a drain electrode (second electrode) 16 and a second end of the drain electrode (second electrode) 16 that faces the source electrode (first electrode) 14 are curved. The source electrode (first electrode) 14 and the drain electrode (second electrode) 16 are annular, and the first end and the second end are circular annular. A distance between the first end and the second end is fixed.

The ultrasonic wave amplification is the resonance phenomenon. Thus, currents flow in various directions (solid line arrows in the drawing) and, when the directions are not aligned, the resonance phenomenon is less likely to occur. Accordingly, the insulation breakdown due to the electric field concentration and the destruction of crystal are less likely to occur.

Hereinabove, according to this embodiment, since the resonance phenomenon due to the ultrasonic wave amplification hardly occurs, a transistor device with enhanced reliability is realized.

The contact of the source electrode (first electrode) 14 and the drain electrode (second electrode) 16 with the GaN-based semiconductor layer 12 is preferably the ohmic contact.

The first end and the second end may not have a circular shape and may have an elliptical shape or a semicircular shape.

### Fifteenth Embodiment

A semiconductor device of this embodiment is similar to the semiconductor device of the fourteenth embodiment, except that the semiconductor device of this embodiment is a diode having no third electrode. Accordingly, the description of the contents overlapped with those of the fourteenth embodiment is omitted.

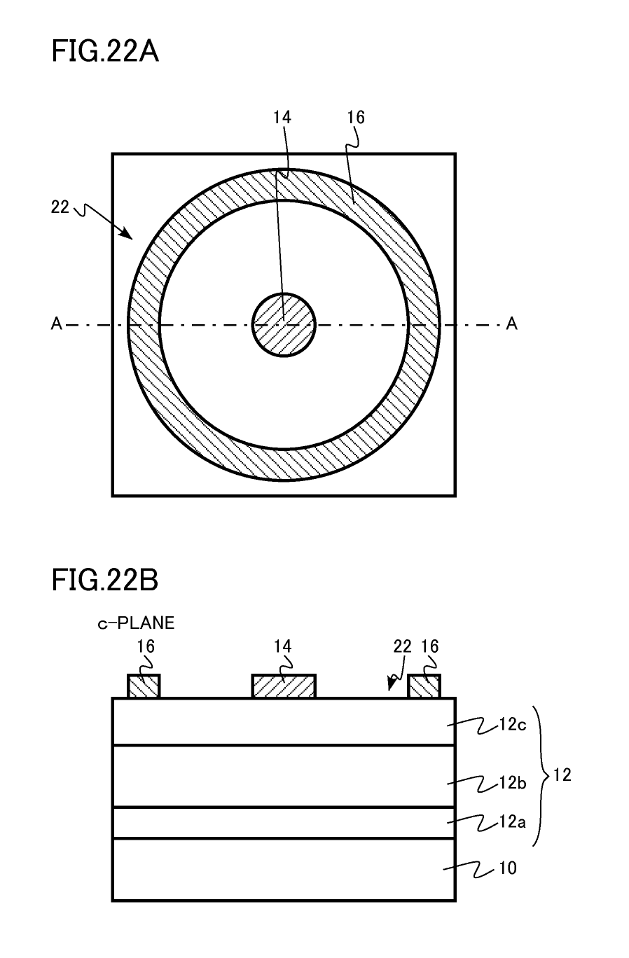

FIGS. 22A and 22B are schematic diagrams of the semiconductor device of this embodiment. FIG. 22A is a schematic top view, and FIG. 22B is an A-A cross-sectional view of FIG. 22A. The semiconductor device of this embodiment is a schottky barrier diode (SBT) using a GaN-based semiconductor.

The semiconductor device of this embodiment includes a substrate 10, a GaN-based semiconductor layer 12, an anode electrode (first electrode) 24, a cathode electrode (second electrode) 26, an element isolation region 20, and an active region (element region) 22. One of the contact between the anode electrode (first electrode) 24 and the GaN-based semiconductor layer 12 and the contact between the cathode electrode (second electrode) 26 and the GaN-based semiconductor layer 12 is the schottky contact, and the other is the ohmic contact.

A first end of the anode electrode (first electrode) 24 that faces the cathode electrode (second electrode) 26 and a second end of the cathode electrode (second electrode) 26 that faces the anode electrode (first electrode) 24 are curved. The anode electrode (first electrode) 24 and the cathode electrode (second electrode) 26 are annular, and the first end and the second end are circular annular. A distance between the first end and the second end is fixed.

In this embodiment, currents flow in various directions. Accordingly, the ultrasonic wave amplification is not less likely to occur, and the resonance phenomenon due to the ultrasonic wave amplification hardly occurs.

Hereinabove, according to this embodiment, since the resonance phenomenon due to the ultrasonic wave amplification hardly occurs, a diode with enhanced reliability is realized.

### Sixteenth Embodiment

A semiconductor device of this embodiment is similar to the semiconductor device of the fourteenth embodiment, except that a surface of a GaN-based semiconductor layer has an angle of not less than 0 degree and not more than 5 degrees with respect to an m-plane or an a-plane. Accordingly, the description of the contents overlapped with those of the fourteenth embodiment is omitted.

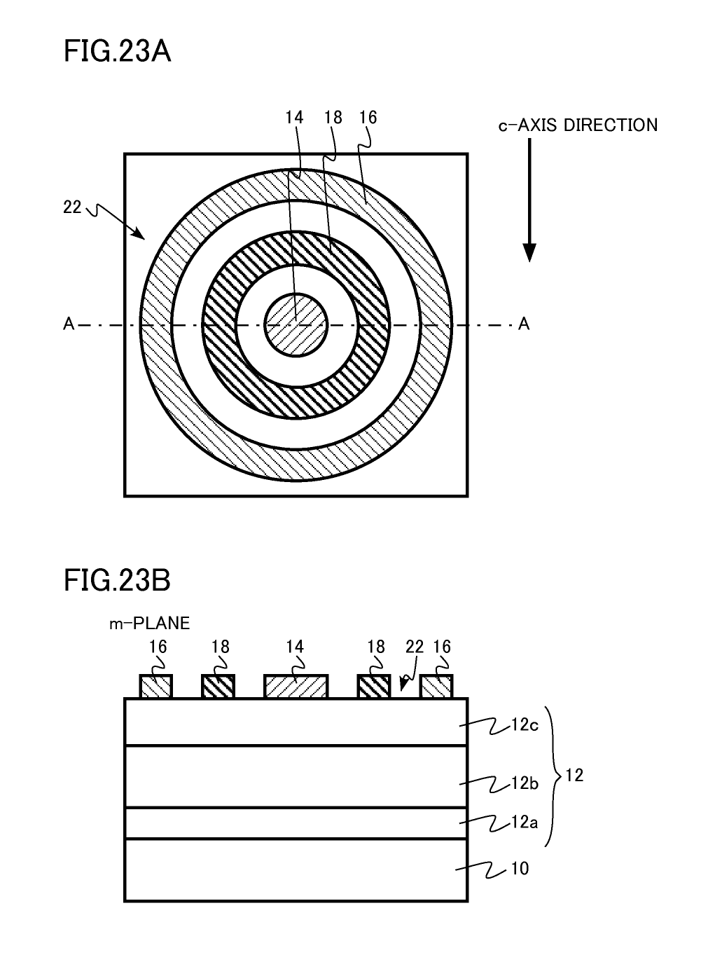

FIGS. 23A and 23B are schematic diagrams of the semiconductor device of this embodiment. FIG. 23A is a schematic top view, and FIG. 23B is an A-A cross-sectional view of FIG. 23A.

A first end of a source electrode (first electrode) 14 that faces a drain electrode (second electrode) 16 and a second end of the drain electrode (second electrode) 16 that faces the source electrode (first electrode) 14 are curved. The source electrode (first electrode) 14 and the drain electrode (second electrode) 16 are annular, and the first end and the second end are circular annular. A distance between the first end and the second end is fixed.

Hereinabove, according to this embodiment, since the resonance phenomenon due to the ultrasonic wave amplification hardly occurs, a transistor device with enhanced reliability is realized. A rate in which a direction of the electric field applied to the source electrode (first electrode) 14 and the drain electrode (second electrode) 16 and a c-axis direction coincide with each other is small. Accordingly, since the resonance phenomenon due to the ultrasonic wave amplification more hardly occurs, the reliability of the transistor device is further enhanced.

In the first to sixteenth embodiments, the example in which the GaN-based semiconductor layer has a stacked structure including the GaN layer and the AlGaN layer, and the surface of the GaN-based semiconductor layer is the AlGaN layer has been mainly described. However, GaN-based semiconductors having other compositions may be applied as the GaN-based semiconductor layer, and different stacked structures may be applied.

While certain embodiments have been described, these embodiments have been presented by way of example only, and are not intended to limit the scope of the inventions. Indeed, a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a GaN-based semiconductor layer having a surface with an angle of not less than 0 degree and not more than 5 degrees with respect to an m-plane or an a-plane;
a first electrode provided above the surface, the first electrode having a first end; and
a second electrode provided above the surface to space apart from the first electrode, the second electrode having a second end facing the first end, a direction of a segment connecting an arbitrary point of the first end and an arbitrary point of the second end being different from a c-axis direction of the GaN-based semiconductor layer.

2. The device according to claim 1, wherein the first end and the second end are parallel to each other.

3. The device according to claim 2, wherein the first end and the second end are parallel to the c-axis direction.

4. The device according to claim 1, wherein the GaN-based semiconductor layer has a stacked structure comprising a GaN layer and an AlGaN layer, and the surface is a surface of the AlGaN layer.

5. The device according to claim 1, further comprising a third electrode provided between the first electrode and the second electrode.

6. The device according to claim 5, wherein a contact of the first electrode and the second electrode with the GaN-based semiconductor layer is an ohmic contact.

7. A semiconductor device comprising:
a GaN-based semiconductor layer;
a first electrode provided above a surface of the GaN-based semiconductor layer, the first electrode having a first end; and
a second electrode provided above the surface to space apart from the first electrode, the second electrode having a second end facing the first end, the second end being not parallel to the first end.

8. The device according to claim 7, wherein the first end and the second end are linear.

9. The device according to claim 7, wherein the first end or the second end has a step-like shape.

10. The device according to claim 7, wherein the first end or the second end is curved.

11. The device according to claim 7, further comprising a third electrode provided between the first electrode and the second electrode.

12. The device according to claim 11, wherein a contact of the first electrode and the second electrode with the GaN-based semiconductor layer is an ohmic contact.

13. A semiconductor device comprising:
a GaN-based semiconductor layer;
a first electrode provided above a surface of the GaN-based semiconductor layer, the first electrode having a curved first end; and
a second electrode provided above the surface to space apart from the first electrode, the second electrode having a curved second end facing the first end.

14. The device according to claim 13, wherein the first end and the second end are annular.

15. The device according to claim 13, further comprising a third electrode provided between the first electrode and the second electrode.

16. The device according to claim 15, wherein a contact of the first electrode and the second electrode with the GaN-based semiconductor layer is an ohmic contact.
